(19) United States
(12) Patent Application Publication
(10) Pub. No.: US 2010/0164482 A1
(43) Pub. Date: Jul. 1, 2010

(54) CENTERING DEVICE FOR ELECTRONIC COMPONENTS, PARTICULARLY ICS

(75) Inventor: Johann Pötzinger, Fischbachau (DE)

Correspondence Address: NIXON & VANDERHYE, PC, 901 NORTH GLEBE ROAD, 11TH FLOOR, ARLINGTON, VA, 22203, US

(73) Assignee: MULTITEST ELEKTRONISCHE SYSTEME GMBH, Rosenheim (DE)

(21) Appl. No.: 12/445,373

(22) PCT Filed: Apr. 24, 2008
(86) PCT No.: PCT/EP08/03314

§ 371 Date: Apr. 13, 2009

(30) Foreign Application Priority Data
May 11, 2007 (DE) 10 2007 022 690.1

(51) Int. Cl. G01R 31/28; G01R 1/04

(52) U.S. Cl. 324/158.1

(57) ABSTRACT

A centering device for electronic components, particularly for ICs, has at least one centering unit comprising two L-shaped centering elements and two coupling elements. The centering elements and coupling elements are hinged together such that a pivoting movement of the coupling elements is forcibly coupled to a parallel displacement of the centering elements, thus causing a widening or narrowing of a centering opening for the components.

Electronic components, particularly IC's, are conventionally subjected to electrical tests after manufacture to test the functionality thereof.

For this purpose, it is known to use handling devices for feeding the components to a testing head of an electronic test means and removing them from the testing head again after the testing process, in order to sort the components as a function of the test result. The handling devices generally also have a feed means with suction tools, with which the components to be tested are sucked up by vacuum and fed to a contact socket on the testing head side.

Because the contact points on the contact socket are very close to one another, particularly when very small components are to be tested, on the one hand the suction tools must be able to move very precisely, and on the other hand the components must be disposed in a precisely defined position relative to the suction tools. For the latter purpose it is conventional to use centering devices, which are arranged shortly before the contact socket. However, precise centering is difficult to achieve, particularly with very small components for which the contacts are very close to one another, if the component takes up a position which no longer lies in a defined region relative to the feed means because of differences in overall dimensions.

The object of the invention is to provide a centering means with which even components with relatively great differences from the standard size, and even very small components, can be centered correctly and thus be contacted well. Furthermore, the centering device should be of a small size and be easy to operate.

This object is achieved in accordance with the invention by the features of claim 1. Advantageous embodiments of the invention are disclosed in the sub-claims.

According to the invention, the centering device comprises at least one centering unit with two L-shaped centering elements, each of which comprises a centering arm with a centering surface and a cross-arm. The centering elements are arranged alongside one another in a ring shape in a plane, in such a way that the centering surfaces of the two centering arms face one another with mutual spacing. Furthermore, the two cross-arms also face one another with mutual spacing, in such a way that the centering elements surround a centering opening for the component to be centered. The centering unit further comprises two coupling elements, which are pivotable about two mutually parallel pivot axes arranged perpendicular to the plane of the centering elements, and are hinged on opposite sides of the centering opening in one case to one centering element and in the other case to the other centering element, in such a way that a pivoting movement of the coupling elements is positively coupled to a change in the distance between the centering arms.

In the centering unit according to the invention, the two L-shaped centering elements are positively coupled in such a way that the centering opening for the component can be widened or narrowed evenly on both sides. The two opposite sides of the components make contact with corresponding centering surfaces, allowing precise centering of the component even with relatively large differences in the dimensions of the body of the component. Furthermore, the centering device according to the invention can be kept relatively small, in such a way that it uses only a small amount of space. The centering device has a low susceptibility to faults and very low wear.

In an advantageous embodiment, the centering arms comprise ramps for the components in the region of the centering surfaces. These ramps mean that the component can be pressed into the centering opening in a simple manner, the centering arms being pushed apart in opposite directions by the component. In this case it is expedient for the centering arms to be biased in the direction of approach, for example by spring force.

In an advantageous embodiment, the centering elements and coupling elements are formed in the shape of plates and lie in the same plane. In this manner, a very flat compact arrangement can be provided.

In a particularly advantageous embodiment, the coupling elements together with the cross-arms of the centering elements form a parallelogram. In this way, the cross-arms always remain parallel even when displaced in the longitudinal direction thereof, and this inevitably means that the inner centering surfaces of the centering arms also remain aligned parallel to one another in any position of the centering elements.

In an advantageous embodiment, the centering elements and coupling elements are produced from a single plate element, the hinge connections between the coupling elements and centering elements consisting of thin, elastically deformable webs of the plate element. In this way, a very flat compact arrangement can be provided, requiring no additional hinge or connection means between the centering elements and coupling elements.

In an advantageous embodiment, an actuation device for displacing the centering elements is functionally connected to the centering elements and comprises pivot levers which are pivotable about a pivot axis arranged parallel to the plane of the centering elements. By means of an actuation device of this type, the centering elements can be guided apart from one another in a simple manner so that the component can be removed through the centering opening of the centering unit again after the testing process.

In an advantageous embodiment, the feed means can be brought into entrainment engagement with at least one pivot lever, in such a way that the pivot lever can be pivoted by the movement of the feed means into such a position as to displace the centering elements outwards in opposite directions. Thus, no additional drive is required for sliding out the centering elements into the release position thereof. This is instead brought about by the backwards movement of the feed means.

In an advantageous embodiment, the pivot levers comprise an engagement portion, which engages with the centering elements, and a locking portion, it being possible for the feed means to he locked to the locking portion by means of a ball and spring locking device. With a ball and spring locking device of this type, the pivot levers may be coupled to and uncoupled from the feed means in a particularly simple manner.

In an advantageous embodiment, two centering units are arranged parallel to one another, adjacent and rotated by 90° in opposite directions, in such a way that the component can be centered from four sides. In this way, particularly good centering of the component can be achieved at the same time as very compact dimensions of the centering device.

In an advantageous embodiment, the centering surfaces are formed by one of the two centering units on projections which project, perpendicular to the plane of the centering elements, into the region of the other centering unit in such a way that the component is centered on all four sides simultaneously.

In the following, the invention will be described in greater detail by way of example and by means of the drawings, in which:

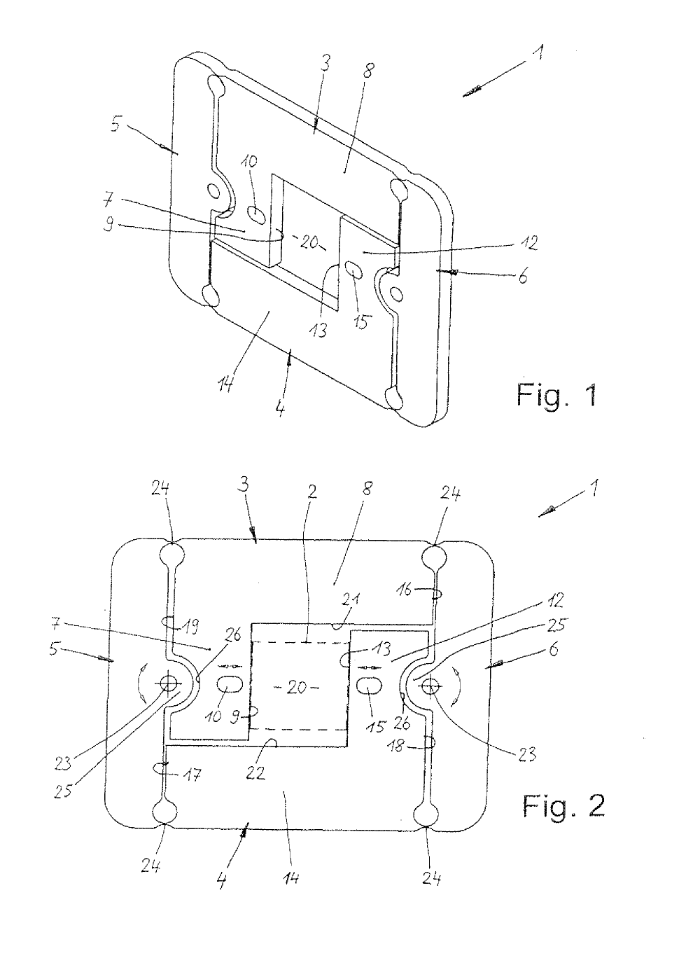

FIG. 1 is a perspective view of a centering unit of the centering means according to the invention,

FIG. 2 is a side view of the centering unit of FIG. 1 with a component, shown in broken lines, having been introduced,

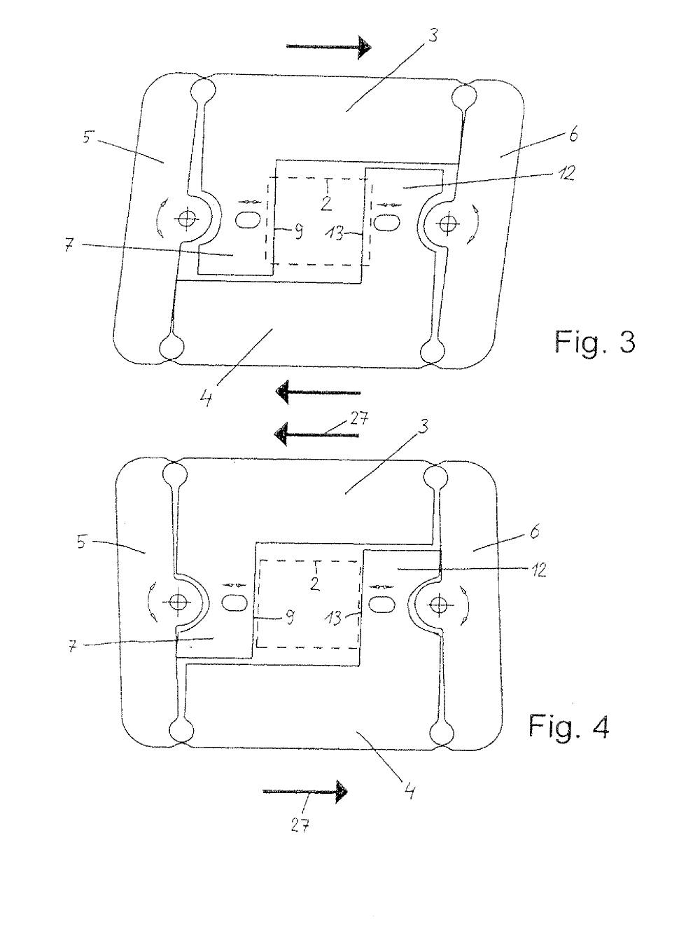

FIG. 3 shows the centering unit of FIG. 2 in a starting position before the introduction of the component,

FIG. 4 shows the centering unit of FIG. 2 in a release position for releasing the component,

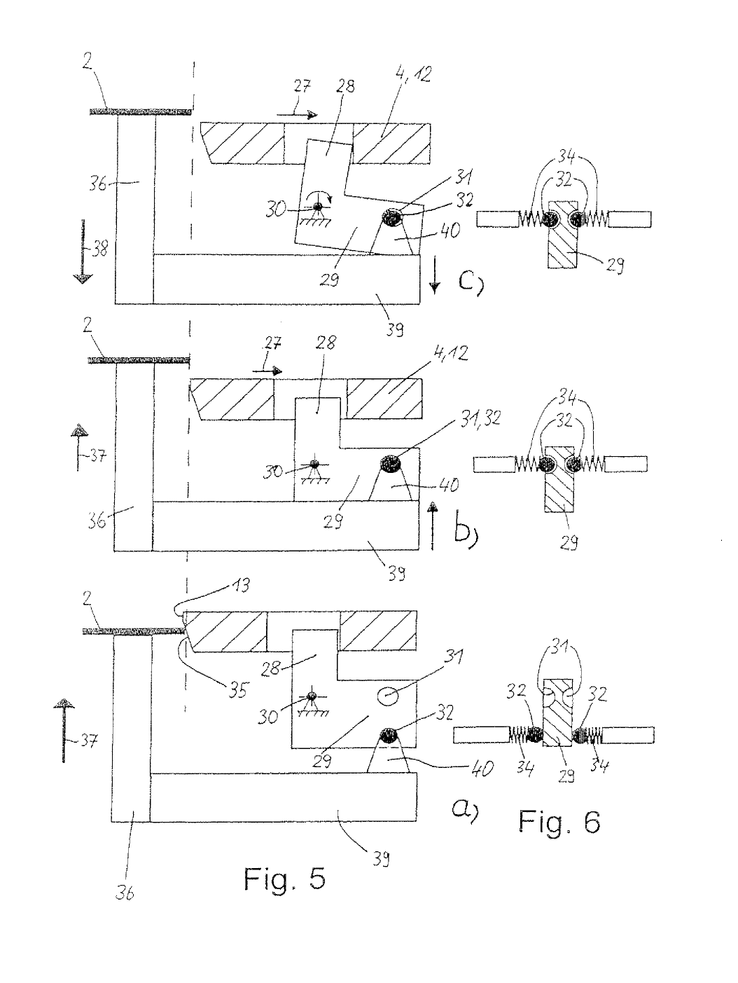

FIG. 5 is a schematic drawing of an actuation device engaging in the centering arm in three different positions a, b and c of the feed means,

FIG. 6 is a schematic drawing of a ball and spring locking device, which cooperates with the actuating device configured as a pivot lever, in the three positions a, b and c of FIG. 5,

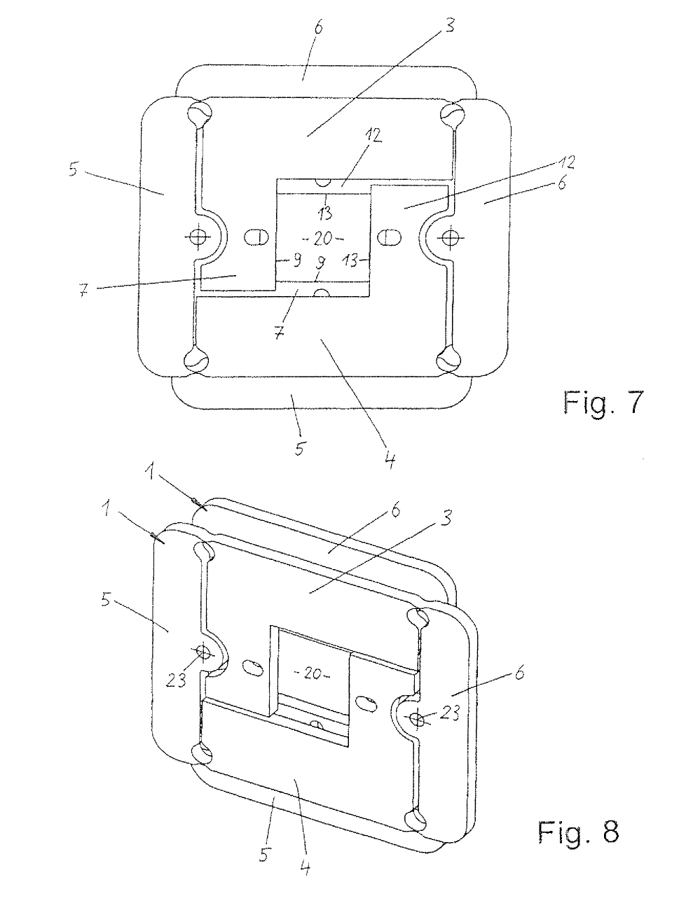

FIG. 7 is a side view of a centering device with two adjacent centering units which are arranged so as to be rotated by 90° in opposite directions,

FIG. 8 is a perspective view of the centering device of FIG. 7,

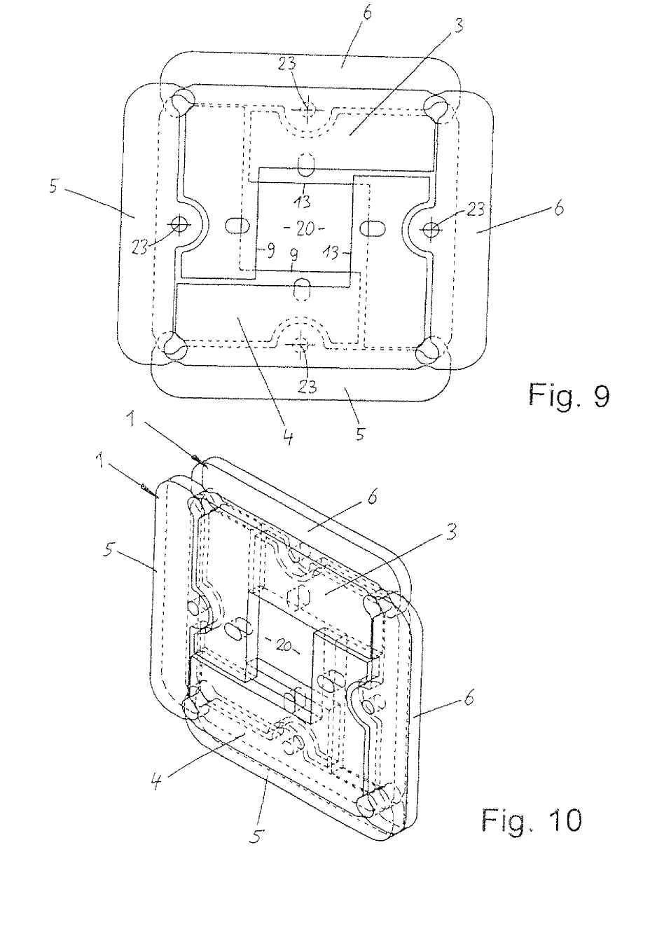

FIG. 9 is a drawing corresponding to FIG. 7, in which the edges which are not visible are marked in broken lines, and

FIG. 10 is a perspective view corresponding to FIG. 8, in which the edges which are not visible are marked in broken lines.

FIGS. 1 to 4 show a centering unit 1 of a centering device for electronic components 2 which comprise rectangular component bodies.

As is shown, the centering unit 1 comprises two L-shaped centering elements 3, 4 and two coupling elements 5, 6.

The centering element 3 comprises a centering arm 7 and a cross-arm 8 extending at a right angle thereto. A centering surface 9 is disposed on the inner side of the centering arm 7. A through-hole 10 is further disposed in the centering arm 7, into which hole there projects a pivot lever (shown in FIG. 5 and described in greater detail below) of an actuation means (not shown in greater detail) for opening the centering means.

In the present case, the centering element 4 is formed so as to be identical to the centering element 3 and likewise comprises a centering arm 12 with an centering surface on the inside, a cross-arm 14 arranged perpendicular to the centering arm 12, and a through-hole 15 in the centering arm 12, in which hole a further pivot lever 11 of the actuation means engages.

The two centering elements 3, 4 are point-symmetric about the centre point of the centering unit 1 and are arranged in a ring shape in the same plane. The two centering arms 7, 12 and therefore also the two centering surfaces 9, 13 thus extend parallel to and at a distance from one another. The two cross-arms 8, 14 likewise extend parallel to and at a distance from one another. The cross-arms 8, 14 in this case have a length such that the narrow end faces 16, 17 thereof extend approximately up to the outer longitudinal faces 18, 19 of the lower and upper centering elements 4, 3 respectively. The centering elements 3, 4 are thus arranged in such a way that the outer edges thereof approximately form a rectangle.

By virtue of this arrangement, the centering elements 3, 4 delimit a rectangular centering opening 20 for the components 2. The components 2 introduced into the centering opening 20 are thus centered on opposite sides by the centering surfaces 9, 13. The inner longitudinal sides 21, 22 of the upper and lower cross-arms 8, 14 are however at a greater distance from one another, in such a way that there is a sufficient distance between the introduced component 2 and the cross-arms 8, 14 that the components 2 do not come into contact with the cross-arms 8, 14.

In the embodiment shown, the two coupling elements 5, 6 consist of elongate, pivotable strips, which are arranged on opposite sides of the centering opening 20 and axially symmetrically about the vertical central axis of the centering unit 1. Like the centering elements 2, 4, the coupling elements 5, 6 consist of plate-shaped elements of equal thickness, which are all arranged in the same plane and thus result in a two-dimensional, planar formation. The coupling elements 5, 6 are pivotable about mutually parallel pivot axes 23. In the shown embodiment, the pivot axes 23 are disposed in the centre as seen in the longitudinal direction of the coupling elements 5, 6, and thus in the central plane of the centering unit 1.

The coupling elements 5, 6 are at some distance from the centering elements 3, 4 and hinged, only at the end regions thereof, to the centering elements 3, 4, by means of thin, elastically deformable webs 24. The two webs 24, each of which is associated with a coupling element 5, 6, lie in the same vertical plane as the associated axis of rotation 23 in the shown embodiment. To make this possible, the coupling elements 5, 6 each comprise a lug 25 projecting in the direction of the centering arms 7, 12, and the centering arms 7, 12 comprise corresponding recesses 26 in the outer edge regions thereof.

The hinged connections with the thin, elastically deformable webs 24 make it possible to produce the two centering elements 3, 4 together with the coupling elements 5, 6 from a single plate element, in such a way that no additional connection means need subsequently be mounted. However, it is also easily possible to produce the coupling elements 5, 6 separately from the centering elements 3, 4 and subsequently to connect them with appropriate articulations.

By virtue of this arrangement, as can be seen in FIGS. 3 and 4, a pivoting movement of the coupling elements 5, 6 about the pivot axis 23 thereof results in a parallel displacement of the centering elements 3, 4 in the opposite direction, and this leads to a narrowing or broadening of the centering opening 20. The centering surfaces 9, 13 of the centering arms 7, 12 always remain parallel to one another in the process.

FIG. 3 shows the centering unit 1 in a starting position in which the centering arms 7, 12 are as close as possible to one another. The centering arms 7, 12 may be biased into this starting position by springs. As is shown in FIGS. 3 and 5, the width of the centering openings 20, i.e. the distance between the centering surfaces 9, 13, is smaller in this starting position than the width of the component 2 to be received. By contrast, FIG. 4 shows the centering unit 1 in a release position, in which the centering elements 3, 4 are spread apart in opposite directions in the direction of the arrows 27 to such an extent that the distance between the centering surfaces 9, 13 is greater than the width of the component 2. In this position, the component 2 can be moved back through the centering opening 20 by retraction of the feed means 36 (FIG. 5), without the component 2 striking the centering arms 7, 12.

In the following, the centering process will be explained in greater detail by way of FIGS. 5 and 6. FIG. 5 is a schematic view merely of the right half of centering device according to the invention. The left half, not shown, is arranged as a mirror image thereof.

As can be seen in FIG. 5a, the feed means 36 moves the component 2, which is fixed thereto, in the direction of the arrow 37 when the component 2 is introduced to a contact socket (not shown). The feed means 36 comprises a portion 39 to which a locking ball means 40 is fixed on the side facing towards the pivot lever 11. This locking ball means 40 consists, as can be seen from FIG. 6, of two opposite locking balls 32 which are biased in the direction towards one another by catch springs 34.

The pivot lever 11 has an L shape with an engagement portion 28 and a locking portion 29 arranged at right angles thereto. The pivot lever 11 is pivotable about a stationary axis of rotation 30, which extends parallel to the principal plane of the centering unit 1. For example, the pivot axis 30 may be provided on a support (not shown) which is disposed in the vicinity of the contact socket. The end region of the engagement portion 28 extends into the associated through-hole 10 or 15 of the centering arm 7 or 12 respectively. Furthermore, the engagement portion 28 has sufficient play within the through-hole 10, 15 that the pivoting motion thereof is not impaired and it is possible for the centering elements 3, 4 to move apart from one another to a certain extent in the direction of the arrow 27 without pivoting the pivot lever 11. Two opposite locking depressions 31 are arranged in the locking portion 29, the locking balls 33 being able to enter said depressions when the feed means 36 with the component 2 is moved into the foremost position thereof, in which the contacting process between the component 2 and the contact socket takes place. Thus, the locking balls 32 come into contacting engagement with the pivot lever 11 from different sides and move along the locking portion 29 until they arrive in the locking depressions 31 and are pressed into these by means of the catch springs 34.

If the component 2 is slid forwards in the direction of the arrow 37 by the feed means 36, then the side edges of the component 2 initially strikes a ramp 35 of the centering surfaces 9, 13, because the centering arms 7, 12 are disposed in the tight position shown in FIGS. 3 and 5. When the feed means 36 is slid forwards, the side edges of the component 2 continuously slide the centering arms 7, 12 apart from one another up to the rear, in the direction of feed means, of the ramps, the component 2 simultaneously being slid into the centered position because it abuts the ramps 35 on opposite sides.

After passing the narrowest point of the centering opening 20, the component 2 may be moved further in the direction of the arrow 37 as far as the contact socket, where the connection legs of the component 2 make contact with the corresponding contact points of the contact socket. This position is shown in FIG. 5b. In this position, the portion 39 of the feed means 36 has approached sufficiently close to the pivot lever 11 for the locking halls 32 to engage in the associated locking depressions 31, as can also be seen in FIG. 6b.

If subsequently, as illustrated in FIG. 5c, the feed means 36 is retracted in the direction of the arrow 38 after the end of the test process, then the locking portion 29 of the pivot lever 11 is pulled downwards by the locking ball means 40, causing the pivot lever 11 to be pivoted clockwise. The engagement portion 28 of the pivot lever 11 thus pivots outwards and accordingly entrains the associated centering element 3, 4 outwards in the direction of the arrow 27. In this way, as can be seen in FIG. 5c, the centering opening 20 is widened to such an extent that the component 2 can be pulled back through the centering opening 20 without striking the centering arms 7, 12.

FIGS. 7 to 10 show a second embodiment of the centering means according to the invention, in which the two identical or at least largely identical centering units 1, rotated by 90° in opposite directions, lie against one another. With a centering means of this type, the components 2 may be centered not only in one dimension, but in two dimensions, i.e. from all four sides.

If two centering units 1 are connected to one another in this way, the centering of the component 2 in the first dimension will take place in a different plane from the centering in the direction perpendicular thereto. To avoid this, it is possible to form the centering surfaces 9, 13 on one of the two centering units 1 on projections (not shown) which project perpendicular to the plane of the centering elements into the region of the other centering unit, in such a way that the centering of the component 2 can take place simultaneously in the same plane on all four sides.

1. Centering device for electronic components, particularly IC's, which are introduced to a contacting means by a feed means, comprising at least one centering unit wherein the centering unit comprises:
two L-shaped centering elements, each of which comprises a centering arm with a centering surface and a cross-arm, the centering elements being arranged alongside one another in a ring shape in a plane, in such a way that the centering surfaces of the two centering arms face one another with mutual spacing, and the two cross-arms face one another with mutual spacing, in such a way that the centering elements surround a centering opening for the component to be centered, and
two coupling elements, which are pivotable about two mutually parallel pivot axes arranged perpendicular to the plane of the centering elements, and are hinged on opposite sides of the centering opening in one case to the one centering element and in the other case to the other centering element, in such a way that a pivoting movement of the coupling elements is positively coupled to a change in the distance between the centering arms.

2. Centering device according to claim 1, wherein the centering arms comprise ramps for the components in the region of the centering surfaces.

3. Centering device according to claim 1, wherein the centering elements and coupling elements are formed in the shape of plates and lie in the same plane.

4. Centering device according to claim 1, wherein the coupling elements together with the cross-arms of the centering elements form a parallelogram.

5. Centering device according to claim 1, wherein the pivot axes of the coupling elements are arranged centrally between the ends thereof.

6. Centering device according to claim 1, wherein the centering elements and coupling elements are produced from a single plate element, the articulated connections between the coupling elements and centering elements consisting of thin, elastically deformable webs of the plate element.

7. Centering device according to claim 1, wherein an actuation device for displacing the centering elements is functionally connected to the centering elements and comprises pivot levers which are pivotable about a pivot axis arranged parallel to the plane of the centering elements.

8. Centering device according to claim 7, wherein the feed means can be brought into entrainment engagement with at least one pivot lever, in such a way that the pivot lever can be pivoted by the movement of the feed means into such a position as to displace the centering elements outwards in opposite directions.

9. Centering device according to claim 8, wherein the pivot levers comprise an engagement portion, which engages with the centering elements, and a locking portion, it being possible for the feed means to be locked to the locking portion by means of a ball and spring locking device.

10. Centering device according to claim 1, wherein two centering units are arranged parallel to one another, adjacent and rotated by 90° in opposite directions, in such a way that the component can be centered from four sides.

11. Centering device according to claim 10, wherein the centering surfaces are formed by one of the two centering units on projections which project, perpendicular to the plane of the centering elements, into the region of the other centering unit, in such a way that the component is centered on all four sides simultaneously.
